(19) United States
(12) Patent Application Publication
(10) Pub. No.: US 2010/0159262 A1
(43) Pub. Date: Jun. 24, 2010

(54) DURABLE THERMAL BARRIER COATING COMPOSITIONS, COATED ARTICLES, AND COATING METHODS

(76) Inventors: Ming Fu, Hamilton, OH (US); Brian Thomas Hazel, West Chester, OH (US); Brett Boutwell, West Chester, OH (US); Tobias A. Schaedler, Cincinnati, OH (US); Curtis Alan Johnson, Niskayuna, NY (US); Don M. Lipkin, Niskayuna, NY (US); Douglas G. Konitzer, West Chester, OH (US); Venkat S. Venkataramani, Clifton Park, NY (US)

Correspondence Address: GENERAL ELECTRIC COMPANY, GE AVIATION, ONE NEUMANN WAY MD F16, CINCINNATI, OH, 45215, US

(21) Appl. No.: 12/338,329

(22) Filed: Dec. 18, 2008

(51) Int. Cl. B32B 15/04; C04B 35/48; C23C 4/10; C23C 14/34

(52) U.S. Cl. 428/472; 501/134; 427/453; 204/192.15

(57) ABSTRACT

A composition useful as a thermal barrier coating on a superalloy substrate intended for use in hostile thermal environments. The coating comprises zirconia stabilized in a predominately tetragonal phase. The composition includes a ceramic component consisting essentially of zirconia (ZrO2) or a combination of zirconia and hafnia (HfO2) and a stabilizer component comprising, in combination, a first co-stabilizer selected from YbO1.5, HoO1.5, ErO1.5, TmO1.5, LuO1.5, and combinations thereof, and optionally YO1.5, a second co-stabilizer selected from TiO2, PdO2, VO2, GeO2, and combinations thereof, and a third co-stabilizer comprising TaO2.5. The stabilizer component is present in an amount effective to achieve the predominantly tetragonal phase in the coating.

### BACKGROUND OF THE INVENTION

This invention relates generally to compositions useful as thermal barrier coatings, and more specifically to compositions for durable thermal barrier coatings, coated articles, and coating methods.

Thermal barrier coatings (TBC) are applied on cooled components in high temperature environments in gas turbine engines, such as airfoils, vanes, shrouds, and combustors. Since TBCs protect the underlying metal from excessive temperatures, their durability is a key concern. One increasingly important factor limiting the life of TBCs is impact and erosion damage. Particles ingested into the engine or liberated within the engine impact the coating during operation and can cause considerable loss of coating, which in turn reduces the service life of the component.

A common TBC utilized in the art comprises a single ceramic layer of approximately 7 wt % yttria-stabilized zirconia (7YSZ) on top of the bond coat and superalloy substrate. Improvements to the erosion and impact resistance of a thermal barrier coating and reduction in thermal conductivity are continually sought to prolong the life of the coating and/or allow increased operating temperatures.

Accordingly, it would be beneficial to provide compositions for thermal barrier coatings which are more durable than conventional 7YSZ and which may have a reduced thermal conductivity.

### BRIEF DESCRIPTION OF THE INVENTION

The above-mentioned need or needs may be met by exemplary embodiments which provide a ceramic material suitable for use as a coating, particularly as a thermal barrier coating (TBC), on a component intended for use in a hostile thermal environment, such as the superalloy turbine, combustor and augmentor components of a gas turbine engine. The coating material is a zirconia- or zirconia/hafnia-based ceramic that has a predominantly tetragonal phase crystal structure and is capable of exhibiting both lower thermal conductivity and improved impact resistance in comparison to conventional 6-8 wt % yttria stabilized zirconia (YSZ).

Exemplary embodiments disclosed herein include an as-deposited composition consisting of: a ceramic component consisting essentially of zirconia (ZrO2) or a combination of zirconia and hafnia (HfO2) and a stabilizer component comprising, in combination, a first co-stabilizer selected from the group consisting of: YbO1.5, HoO3, Er2O1.5, TmO1.5, LuO1.5, YO1.5 and combinations thereof, a second co-stabilizer selected from the group consisting of: titanium dioxide (TiO2), palladium dioxide (PdO2), vanadium dioxide (VO2), germanium dioxide (GeO2), and combinations thereof, and a third co-stabilizer consisting of TaO2.5, wherein the stabilizer component is present in an amount effective to achieve the predominantly tetragonal phase in the coating, with the balance being incidental impurities.

Exemplary embodiments disclosed herein include a thermally protected article comprising a superalloy substrate and a thermal barrier coating.

Exemplary embodiments disclosed herein include a method for providing a thermally protected article. Exemplary methods include providing a superalloy substrate; providing a thermal barrier coating on the substrate, wherein the coating comprises a composition, as-deposited, consisting of a ceramic component consisting essentially of zirconia (ZrO2) or a combination of zirconia and hafnia (HfO2), and a stabilizer component comprising, in combination, comprising, in combination, a first co-stabilizer selected from the group consisting of: YbO1.5, HoO3, Er2O1.5, TmO1.5, LuO1.5, YO1.5 and combinations thereof, a second co-stabilizer selected from the group consisting of: titanium dioxide (TiO2), palladium dioxide (PdO2), vanadium dioxide (VO2), germanium dioxide (GeO2), and combinations thereof, and a third co-stabilizer consisting of TaO2.5, wherein the stabilizer component is present in an amount effective to achieve the predominantly tetragonal phase in the coating, with the balance being incidental impurities.

### BRIEF DESCRIPTION OF THE DRAWINGS

The subject matter which is regarded as the invention is particularly pointed out and distinctly claimed in the concluding part of the specification. The invention, however, may be best understood by reference to the following description taken in conjunction with the accompanying drawing figures in which:

FIG. 1 is a perspective view, partially cut away, of a high pressure turbine blade having a thermal barrier coating thereon.

### DETAILED DESCRIPTION OF THE INVENTION

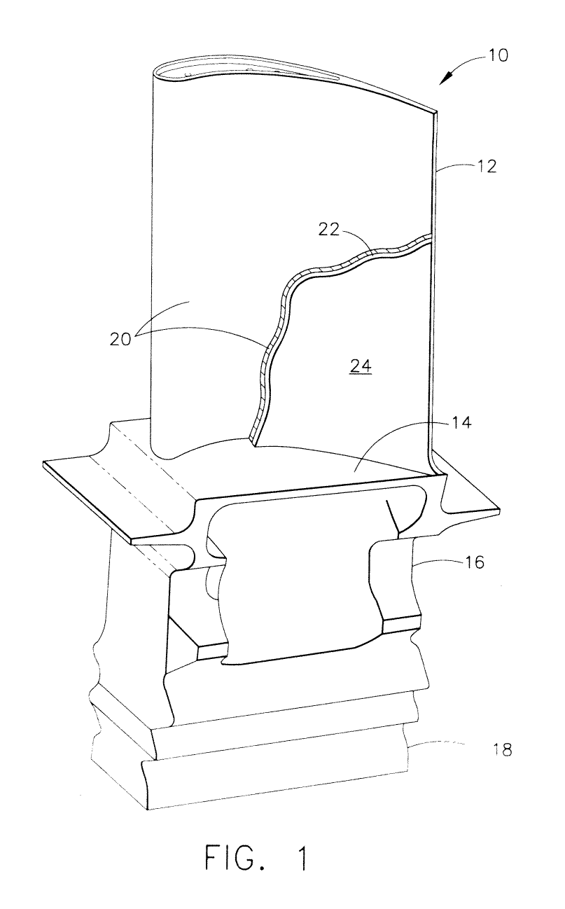

Exemplary embodiments disclosed herein include compositions useful as thermal barrier coatings. The present invention is generally applicable to components subjected to high temperatures, and particularly to components such as the high and low pressure turbine nozzles and blades, shrouds, combustor liners and augmentor hardware of gas turbine engines. An example of a high pressure turbine blade 10 is shown in FIG. 1. The blade 10 generally includes an airfoil 12 against which hot combustion gases are directed during operation of the gas turbine engine, and whose surface is therefore subjected to hot combustion gases as well as attack by oxidation, corrosion and erosion. The airfoil 12 is protected from its hostile operating environment by a thermal barrier coating (TBC) system. The airfoil 12 is anchored to a turbine disk (not shown) with a dovetail 14 formed on a root section 16 of the blade 10. Cooling passages 18 are present in the airfoil 12 through which bleed air is forced to transfer heat from the blade 10. While the embodiments disclosed herein are described with respect to high pressure turbine blades of the type shown in FIG. 1, the principles disclosed are generally applicable to any component on which a thermal barrier coating may be used to protect the component from a hostile thermal environment.

The thermal barrier coating system includes a thermal barrier coating 20 and a bond coat 22 that overlies the surface of a substrate 24, the latter of which is typically a superalloy and the base material of the blade 10. As is typical with TBC systems for components of gas turbine engines, the bond coat 22 is preferably an aluminum-rich composition, such as an overlay coating of an MCrAlX alloy or a diffusion coating such as a diffusion aluminide or a diffusion platinum aluminide of a type known in the art. Aluminum-rich bond coats of this type develop an aluminum oxide (alumina) scale, which grows by oxidation of the bond coat 22. The alumina scale chemically bonds a thermal barrier coating 20, formed of a thermal-insulating material, to the bond coat 22 and substrate 24. The TBC 20 may encompass a porous, strain-tolerant microstructure of columnar grains. As known in the art, such columnar microstructures can be achieved by depositing the coating 20 using a physical vapor deposition technique, such as EBPVD. The coatings described herein are also believed to be applicable to noncolumnar TBC deposited by such methods as thermal spraying, including air plasma spraying (APS). A TBC of this type is in the form of molten “splats,” resulting in a microstructure characterized by irregular flattened grains and a degree of inhomogeneity and porosity. As with prior art TBC's, the coating 20 is intended to be deposited to a thickness that is sufficient to provide the required thermal protection for the underlying substrate 24 and blade 10. In general, the coating thickness may be on the order of about 75 to about 300 micrometers for EB-PVD deposited coatings and 300 to about 1200 micrometers for coatings applied using thermal spray techniques.

Exemplary embodiments disclosed herein relate generally to coating compositions in a ZrO2-HfO2-YbO1.5-TiO2-TaO2.5 system and related compositions. In the following discussion, exemplary as-deposited coating compositions disclosed herein are considered as having a ceramic component and a stabilizer component.

It is believed that TBC durability is related to the degree of tetragonality of the crystal structure (defined as the ratio of the tetragonal unit cell dimensions c/a). The TBC durability is quantified by fracture toughness or particle impact/erosion resistance. YbO1.5 may offer advantages over YO1.5 in the stabilizer component by providing increased phase stability relative to zirconia stabilized with comparable amounts of YO1.5.

In addition, by utilizing YbO1.5 as a stabilizer, the tetragonal phase may be maintained through a greater compositional space in a ZrO2-YbO1.5 system at the relevant temperatures (0-1400° C.), relative to a comparable ZrO2-YO1.5 system. Thus, higher concentrations of stabilizer may be added to reduce the thermal conductivity of the coating while remaining in the tetragonal phase for toughness. The expanded compositional space further allows a greater tolerance for process induced compositional variations.

Additionally, ytterbium (Yb) has a higher atomic mass than yttrium (Y). Embodiments disclosed herein including Yb as a stabilizer are believed to result in reduced thermal conductivity based on a mass disorder theory.

Embodiments disclosed herein include hafnia substituted for up to about 50 mol % zirconia in the ceramic component to reduce thermal conductivity, also based on a mass disorder theory.

Exemplary compositions disclosed herein also include titania (TiO2) as a co-stabilizer to increase the tetragonality (c/a ratio). It is believed that additions of titania to YbO1.5-stabilized zirconia/hafnium increases tetragonality (c/a) of the crystal structure. The higher tetragonality is anticipated to result in a greater coating toughness, i.e., improved erosion and impact resistance.

Exemplary compositions disclosed herein include TaO2.5 as a third co-stabilizer. The inclusion of both TiO2/TaO2.5 as co-stabilizers is believed to increase the coating toughness and hence the durability of the coating. The combination of YbO1.5/TiO2/Ta2O5 is believed to increase the stability of the tetragonal phase of zirconia in the coating.

The exemplary compositions provided above may be modified using the principles discussed above. For example, embodiments disclosed herein may include substitutions of Ho2O3, Er2O3, Tm2O3, Lu2O3, or combinations thereof, (providing tri-valent cations) for all or part of the ytterbia as a first co-stabilizer. These oxides may be substituted for all or part of the ytterbia. Additionally, other small MO2 compounds, where M=Pd, V, Ge, or combinations thereof, (providing smaller tetravalent cations) may be substituted for TiO2 as a second co-stabilizer. Exemplary embodiments disclosed herein may optionally include yttria in the stabilizer component.

An exemplary as-deposited composition may comprise ZrO2-YbO1.5(6-10 mol %)-TiO2-TaO2.5 in combination up to about 20 mol %). Another exemplary as-deposited embodiment includes ZrO2-HfO2(2-50 mol %) (as substituted for ZrO2 in the ceramic component)-YbO1.5(6-10 mol %)-TiO2-TaO2.5 (in combination up to about 20 mol %). In the exemplary compositions, the stabilizer component, i.e., YbO1.5 or its substitutions, TiO2, or its substitutions, and TaO2.5, is present in an amount to provide the desired tetragonal phase in the coating. Thus, the first co-stabilizer may be present in any amount from about 6 to about 10 mol %, the second and third co-stabilizers may be present in any combination, up to about 20 mol %, all relative to the as-deposited coating composition.

Embodiments disclosed herein may be applied to a superalloy substrate using physical vapor deposition techniques (e.g., EB-PVD), thermal spray (e.g., APS, DVM) or other suitable technique.

Thus, embodiments disclosed herein provide compositions suitable as thermal barrier coatings on superalloy substrates. The compositions include a ceramic component including zirconia or a combination of zirconia and from about 2 to about 50 mol % hafnia, and a stabilizer component including a first co-stabilizer, such as YbO1.5, a second co-stabilizer, such as TiO2, and a third co-stabilizer, TaO2.5. The first, second, and third co-stabilizers are present, in combination, in respective amounts to achieve a predominantly tetragonal phase in the coating over the expected temperature range to which the TBC would be subjected if deposited on a gas turbine engine component. The first co-stabilizer may include full or partial substitution of the YbO1.5 with YO1.5, HoO1.5, ErO1.5, TmO1.5, or LuO1.5. The second co-stabilizer may include full or partial substitution of TiO2 with other MO2 oxides where M4+ has an ionic radii less than Zr4+ (e.g., PdO2, VO2, GeO2). The embodiments disclosed herein are believed to have a lower thermal conductivity and greater impact resistance (toughness) than comparable 6-8 wt % yttria stabilized zirconia (YSZ).

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A composition useful as a thermal barrier coating on a superalloy substrate, the coating comprising zirconia stabilized in a predominately tetragonal phase, the composition, as-deposited, consisting of:
a ceramic component consisting essentially of zirconia (ZrO2) or a combination of zirconia and hafnia (HfO2);
a stabilizer component comprising, in combination, a first co-stabilizer selected from the group consisting of: YbO1.5, HoO3, Er2O1.5, TmO1.5, LuO1.5, YO1.5 and combinations thereof, a second co-stabilizer selected from the group consisting of: titanium dioxide (TiO2), palladium dioxide (PdO2), vanadium dioxide (VO2), germanium dioxide (GeO2), and combinations thereof, and a third co-stabilizer consisting of TaO2.5, wherein the stabilizer component is present in an amount effective to achieve the predominantly tetragonal phase in the coating; and
the balance being incidental impurities.

2. The composition according to claim 1 wherein the ceramic component includes from 2 to about 50 mole % hafnia (HfO2), with respect to the coating composition.

3. The composition according to claim 1 wherein the first co-stabilizer includes from about 6 to about 10 mole % YbO1.5, with respect to the coating composition.

4. The composition according to claim 1 wherein the second and third co-stabilizers include, in combination, up to about 20 mol % TiO2 and TaO2.5, with respect to the coating composition.

5. The composition according to claim 1 comprising ZrO2-HfO2-YbO1.5-TiO2-TaO2.5, where HfO2 comprises from 2-50 mol % of the composition, YbO1.5 comprises from 6-10 mol % of the composition, and, in combination, TiO2 and TaO2.5 comprise up to about 20 mol % of the composition.

6. The composition according to claim 5 wherein a portion of the YbO1.5 is substituted by YO1.5.

7. The composition according to claim 5 wherein at least a portion of the TiO2 is substituted by at least one member of the group consisting of palladium dioxide (PdO2), vanadium dioxide (VO2), germanium dioxide (GeO2), and combinations thereof.

8. The composition according to claim 5 wherein at least a portion of the YbO1.5 is substituted by HoO1.5, ErO1.5, TmO1.5, LuO1.5 and combinations thereof.

9. A thermally protected article comprising a superalloy substrate and a thermal barrier coating, wherein the thermal barrier coating comprises an as-deposited composition according to claim 1.

10. The article according to claim 9 wherein the as-deposited composition comprises ZrO2-HfO2-YbO1.5-TiO2-TaO2.5, where HfO2 comprises from 2-50 mol % of the composition, YbO1.5 comprises from 6-10 mol % of the composition, and, in combination, TiO2 and TaO2.5 comprise up to about 20 mol % of the composition.

11. The article according to claim 9, wherein the article comprises a component for a gas turbine engine.

12. The article according to claim 9 wherein the coating has an as-deposited coating thickness, wherein at a predetermined temperature, the coating exhibits a greater impact resistance and a reduced thermal conductivity as compared to a comparable coating consisting essentially of zirconia stabilized with about 7 weight % yttria (7YSZ) and having a comparable as-deposited coating thickness.

13. The article according to claim 9 wherein the as-deposited coating exhibits a columnar microstructure indicative of deposition by a physical vapor deposition technique.

14. The article according to claim 9 wherein the as-deposited coating exhibits a microstructure indicative of application by a thermal spray technique.

15. The article according to claim 10 including at least one of the following:
a) substitution of a first portion of the YbO1.5 with YO1.5;
b) substitution of at least a second portion of the YbO1.5 with at least one member of the group consisting of HoO1.5, ErO1.5, TmO1.5, LuO1.5 and combinations thereof, and
c) substitution of at least a portion of the TiO2 with at least one member of the group consisting of palladium dioxide (PdO2), vanadium dioxide (VO2), germanium dioxide (GeO2), and combinations thereof.

16. The article according to claim 10 further comprising a bond coat layer on a surface of the substrate, and wherein the thermal barrier coating comprises an outermost layer of the article.

17. A method for providing a thermally protected article comprising:
providing a superalloy substrate;
providing a thermal barrier coating on the substrate, wherein the coating comprises a composition, as deposited, consisting of:
a ceramic component consisting essentially of zirconia (ZrO2) or a combination of zirconia and hafnia (HfO2);
a stabilizer component comprising, in combination, a first co-stabilizer selected from the group consisting of: YbO1.5, HoO3, Er2O1.5, TmO1.5, LuO1.5, YO1.5 and combinations thereof, a second co-stabilizer selected from the group consisting of: titanium dioxide (TiO2), palladium dioxide (PdO2), vanadium dioxide (VO2), germanium dioxide (GeO2), and combinations thereof, and a third co-stabilizer consisting of TaO2.5, wherein the stabilizer component is present in an amount effective to achieve the predominantly tetragonal phase in the coating; and
the balance being incidental impurities.

18. The method according to claim 17 wherein the as-deposited composition comprises ZrO2-HfO2-YbO1.5-TiO2-TaO2.5, where HfO2 comprises from 2-50 mol % of the composition, YbO1.5 comprises from 6-10 mol % of the composition, and, in combination, TiO2 and TaO2.5 comprise up to about 20 mol % of the composition.

19. The method according to claim 17 wherein providing the thermal barrier coating includes depositing the composition using a physical vapor deposition technique.

20. The method according to claim 17 wherein providing the thermal barrier coating includes application using a thermal spray technique.
